(19) United States
(12) Patent Application Publication
(10) Pub. No.: US 2012/0044006 A1
(43) Pub. Date: Feb. 23, 2012

(54) DC OFFSET CALIBRATION APPARATUS, DC OFFSET CALIBRATION SYSTEM, AND METHOD THEREOF

(75) Inventors: Shiau-Wen Kao, Hsinchu City (TW); Jia-Hung Peng, Hsinchu City (TW); Ming-Ching Kuo, Chiayi County (TW)

(73) Assignee: INDUSTRIAL TECHNOLOGY RESEARCH INSTITUTE, Hsinchu (TW)

(21) Appl. No.: 12/886,550

(22) Filed: Sep. 20, 2010

(30) Foreign Application Priority Data
Aug. 19, 2010 (TW) 99127786

(51) Int. Cl. H03L 5/00

(52) U.S. Cl. 327/307

(57) ABSTRACT

A DC offset calibration apparatus including a signal processing unit, a comparison unit, a first resistor array, a second resistor array, and a resistor array control unit is provided. The signal processing unit receives an input differential signal and generates an output differential signal. The comparison unit detects and determines a first DC output voltage and a second DC output voltage of the output differential signal and generates a DC offset signal. First ends of the first resistor array and the second resistor array are respectively coupled to a first input terminal and a second input terminal of the signal processing unit. The resistor array control unit adjusts resistances of the first and the second resistor array according to the DC offset signal and a bit code sequence until the DC offset signal enters a transient state, so as to calibrate a DC offset voltage in the output differential signal.

### CROSS-REFERENCE TO RELATED APPLICATION

This application claims the priority benefit of Taiwan application serial no. 99127786, filed on Aug. 19, 2010. The entirety of the above-mentioned patent application is hereby incorporated by reference herein and made a part of this specification.

### TECHNICAL FIELD

The disclosure relates to a DC offset calibration technique, and more particularly, to a calibration technique that compensates for a DC offset voltage by adjusting the resistances of resistor arrays.

### BACKGROUND

Operational amplifier is a major element in wireless communication circuits. An operational amplifier usually receives an input differential signal through the input terminal thereof and generates an output differential signal according to the gain of the operational amplifier. If the input differential signal has an unpredicted DC offset voltage, the quality of the output signal is greatly reduced, or an incorrect output signal may even be generated. Herein the DC offset voltage may be produced by a signal generator at the upper level or caused by device mismatch in the operational amplifier. Thereby, how to eliminate the DC offset has been a major subject in the design of many signal processing systems.

There are two types of DC offset calibration circuits. One type of DC offset calibration circuits generate a voltage inverse to the DC offset voltage by using a negative feedback integrator, so as to eliminate the DC offset caused by device mismatch. Because the negative feedback integrator includes some large elements (for example, capacitors), the negative feedback integrator has to be carefully disposed when it is integrated into a chip, and meanwhile, whether the time spent on eliminating the DC offset is prolonged by the negative feedback effect has to be taken into consideration. The other type of DC offset calibration circuits generate a compensation voltage by using a digital-to-analog converter (DAC), so as to eliminate the DC offset. However, such a DC offset calibration circuit usually adopts a current DAC such that the surface area of the circuit is large and the power consumption thereof is high.

### SUMMARY

A DC offset calibration apparatus, a DC offset calibration system, and a method thereof are introduced herein.

The present disclosure is directed to a DC offset calibration apparatus, wherein the resistances of resistor arrays at the input terminal is adjusted to compensate for a DC offset voltage, so that the surface area and the power consumption of the circuit can be both reduced. In addition, the DC offset calibration apparatus adopts an open-circuit design such that the response of the circuit is made rapid and stable.

The present disclosure provides a DC offset calibration apparatus. The DC offset calibration apparatus includes a signal processing unit, a comparison unit, a first resistor array, a second resistor array, and a resistor array control unit. The signal processing unit has a first input terminal and a second input terminal. The signal processing unit receives an input differential signal and generates an output differential signal. The comparison unit is coupled to the signal processing unit. The comparison unit detects and determines the levels of a first DC output voltage and a second DC output voltage of the output differential signal to generate a DC offset signal, wherein the DC offset signal contains the polarity sign of a DC offset voltage. A first end of the first resistor array is coupled to the first input terminal of the signal processing unit, a first end of the second resistor array is coupled to the second input terminal of the signal processing unit, and second ends of the first resistor array and the second resistor array both receive a compensation voltage. The resistor array control unit adjusts the resistances of the first resistor array and the second resistor array according to the DC offset signal, so as to calibrate a DC offset voltage in the output differential signal.

The present disclosure also provides a DC offset calibration method. This method is suitable for being applied between a signal processing unit, a first resistor array, and a second resistor array. The signal processing unit has a first input terminal and a second input terminal, and the signal processing unit generates an output differential signal. A first end of the first resistor array is coupled to the first input terminal of the signal processing unit, a first end of the second resistor array is coupled to the second input terminal of the signal processing unit, and second ends of the first resistor array and the second resistor array both receive a compensation voltage. The DC offset calibration method includes following steps. The levels of a first DC output voltage and a second DC output voltage of the output differential signal are detected and determined to generate a DC offset signal. The first resistor array is adjusted to have a first predetermined resistance according to the DC offset signal. The resistance of the second resistor array is adjusted according to the sequence of the bit codes until the DC offset signal enters a transient state, so as to calibrate the DC offset voltage in the output differential signal.

The present disclosure further provides a DC offset calibration system including N signal processing units, N first resistor arrays, N second resistor arrays, a comparison unit, and a resistor array control unit, wherein N is a positive integer. Each of the signal processing units includes a first input terminal and a second input terminal. Each of the signal processing units receives an input differential signal and generates an output differential signal. A first end of the i^{th} first resistor array is coupled to the first input terminal of the i^{th} signal processing unit, a first end of the i^{th} second resistor array is coupled to the second input terminal of the i^{th} signal processing unit, and second ends of the i^{th} first resistor array and the i^{th} second resistor array receive a compensation voltage, wherein i is a positive integer and 1≦i≦N. The comparison unit detects and determines the levels of a first DC output voltage and a second DC output voltage of the output differential signal of the i^{th} signal processing unit to generate a DC offset signal. The resistor array control unit adjusts the resistances of the i^{th} first resistor array and the i^{th} second resistor array according to the DC offset signal, so as to calibrate a DC offset voltage in the output differential signal of the i^{th} signal processing unit.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a block diagram of a DC offset calibration apparatus according to a first embodiment of the present disclosure.

FIG. 2 illustrates the circuit structure of a resistor array R_{A1} according to the first embodiment of the present disclosure.

FIG. 3 illustrates the circuit structure of a resistor array R_{B1} according to the first embodiment of the present disclosure.

FIG. 4 is a flowchart of a DC offset calibration method according to the first embodiment of the present disclosure.

FIG. 5 is a diagram illustrating a DC offset calibration method according to the first embodiment of the present disclosure.

FIG. 6 is a diagram of the resistor array R_{B1} in FIG. 3.

FIG. 7 is a block diagram of a DC offset calibration apparatus according to a second embodiment of the present disclosure.

FIG. 8 is a block diagram of a DC offset calibration system according to a third embodiment of the present disclosure.

### DETAILED DESCRIPTION OF DISCLOSED EMBODIMENTS

Reference will now be made in detail to exemplary embodiments of the present disclosure, examples of which are illustrated in the accompanying drawings, wherein like reference numerals refer to the like elements throughout.

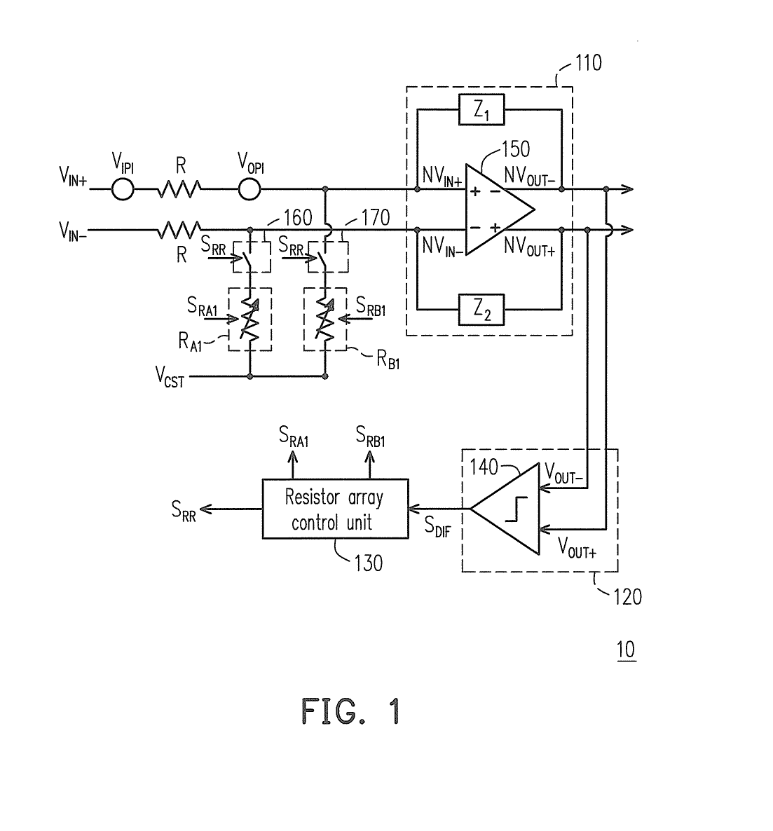

FIG. 1 is a block diagram of a DC offset calibration apparatus 10 according to a first embodiment of the present disclosure. Referring to FIG. 1, the DC offset calibration apparatus 10 includes a signal processing unit 110, a comparison unit 120, a resistor array R_{A1}, a resistor array R_{B1}, and a resistor array control unit 130. The signal processing unit 110 may be a signal processing circuit composed of an operational amplifier 150, a impedor Z₁, and a impedor Z₂, and the signal processing unit 110 has an input terminal NV_{IN+}, an input terminal NV_{IN-}, an output terminal NV_{OUT+}, and an output terminal NV_{OUT-}. For the convenience of description, in the present embodiment, the impedances of the impedor Z₁ and the impedor Z₂ are both Z.

Referring to FIG. 1, the comparison unit 120 is coupled to the signal processing unit 110. The comparison unit 120 detects and determines the voltage levels of a DC output voltage V_{OUT+} and a DC output voltage V_{OUT-} of an output differential signal, so as to generate a DC offset signal S_{DIF}. In the present embodiment, the comparison unit 120 is described as a hysteresis comparator 140. Besides, a first end of the resistor array R_{A1} in FIG. 1 is coupled to the input terminal NV_{IN-} of the signal processing unit 110 through a switch 160, a first end of the resistor array R_{B1} is coupled to the input terminal NV_{IN+} of the signal processing unit 110 through a switch 170, and second ends of the resistor array R_{A1} and the resistor array R_{B1} both receive a compensation voltage V_{CST}. The switch 160 and the switch 170 receive a break-off signal S_{RR} from the resistor array control unit 130 through the control terminals thereof and control the coupling between the resistor array R_{A1} and the resistor array R_{B1} and the input terminal NV_{IN-} and the input terminal NV_{IN+} according to the break-off signal S_{RR}. The resistor array control unit 130 generates a resistor array control signal S_{RA1} and a resistor array control signal S_{RB1} according to the DC offset signal S_{DIF}, so as to respectively adjust the resistances of the resistor array R_{A1} and the resistor array R_{B1} and calibrate a DC offset voltage in the output differential signal.

How to adjust resistances of the resistor array R_{A1} and the resistor array R_{B1} and accordingly calibrate the DC offset voltage in the output differential signal will be explained herein formula deduction. Referring to FIG. 1, ideally, the signal processing unit 110 receives an input differential signal through the input terminal NV_{IN+} and the input terminal NV_{IN-} and generates the output differential signal through the output terminal NV_{OUT+} and the output terminal NV_{OUT-}. However, in an actual situation, a signal processing unit at the upper level may produce a DC offset voltage V_{IP1} while transmitting the input differential signal or other factors, and the operational amplifier 150 of the signal processing unit 110 may produce a DC offset voltage V_{OP1} due to device mismatch therein. The resistance R in the present embodiment is the circuit impedance (for example, circuit resistance) before the input terminal N_{VIN+} and the input terminal N_{VIN-} of the signal processing unit 110. Aforementioned DC offset voltage V_{IP1}, the DC offset voltage V_{OP1}, and the resistance R are all assumptions in the present embodiment, and the values thereof can be changed according to the actual requirement by those skilled in the art.

The DC output voltage V_{OUT+} and the DC output voltage V_{OUT-} can be calculated through following formulas (1) and (2), wherein the common mode voltage V_{CMIN} is a DC voltage on the input terminal NV_{IN+} and the input terminal NV_{IN-}:

$$\begin{matrix}[ \frac{{V}_{IN +} - {V}_{1 P 1} - {V}_{OP 1} - {V}_{CMIN}}{R} + \frac{{V}_{CST} - {V}_{CMIN}}{RB 1} ] \times Z = {V}_{OUT -} & ( 1 ) \\ [ \frac{{V}_{IN -} - {V}_{CMIN}}{R} + \frac{{V}_{CST} - {V}_{CMIN}}{RA 1} ] \times Z = {V}_{OUT +} & ( 2 )\end{matrix}$$

Because the signal processing unit 110 works in a differential mode, the DC input voltages V_{IN+} and V_{IN-} of the input differential signal should have the same voltage level, and the DC output voltages V_{OUT+} and V_{OUT-} of the output differential signal should also have the same voltage level. Namely, V_{IN+}=V_{IN-} and V_{OUT+}=V_{OUT-}. Thus, the following formula (3) is obtained by subtracting the formula (2) from the formula (1):

$$[ \frac{{V}_{IN +} - {V}_{1 P 1} - {V}_{OP 1} - {V}_{CMIN}}{R} - \frac{{V}_{IN -} - {V}_{CMIN}}{R} + \frac{{C}_{CST} - {V}_{CMIN}}{RB 1} - \frac{{V}_{CST} - {V}_{CMIN}}{RA 1} ] \times Z = {V}_{OUT +} - {V}_{OUT -} , \\ ⇒ [ \frac{{V}_{IN +} - {V}_{IN -}}{R} - \frac{{V}_{1 P 1} + {V}_{OP 1}}{R} + ( {V}_{CST} - {V}_{CMIN} ) \times ( \frac{1}{RB 1} - \frac{1}{RA 1} ) ] \times Z = {V}_{OUT +} - {V}_{OUT -} , \\ ⇒ \frac{{V}_{1 P 1} + {V}_{OP 1}}{R} = ( {V}_{CST} - {V}_{CMIN} ) \times ( \frac{1}{RB 1} - \frac{1}{RA 1} ) = ( {V}_{CST} - {V}_{CMIN} ) \times ( \frac{RA 1 - RB 1}{RA 1 \times RB 1} ) \qquad ( 3 )$$

Based on foregoing description and formula deduction, if a constant value is obtained by subtracting the common mode voltage V_{CMIN} from the compensation voltage V_{CST}, in the present embodiment, the resistances of the resistor arrays B_{A1} and R_{B1} are adjusted to calibrate the DC offset voltages V_{IP1} and V_{OP1}, so as to reduce the affection of the DC offset voltages V_{IP1} and V_{OP1} on the output differential signals V_{OUT+} and V_{OUT-}.

The present embodiment provides the circuit structures of the resistor arrays R_{A1} and R_{B1} and a DC offset calibration method according to the spirit of the present disclosure. The DC offset calibration apparatus 10 sequentially and precisely adjusts the resistances of the resistor arrays R_{A1} and R_{B1} by using different bit codes, so as to calibrate the DC offset voltage. In the present embodiment, two kinds of bit codes (M most significant bits (MSB) and N least significant bits (LSB), wherein M and N are both positive integers) are taken as examples of aforementioned different bit codes. Thus, the resistor array control signal S_{RA1} generated by the resistor array control unit 130 is composed of LSB switch control signals LS₁-LS_{N} and MSB switch control signals MS₁-MS_{M}, and the resistor array control signal S_{RBI} is composed of LSB switch control signals LD₁-LD_{N} and MSB switch control signals MD₁-MD_{M}.

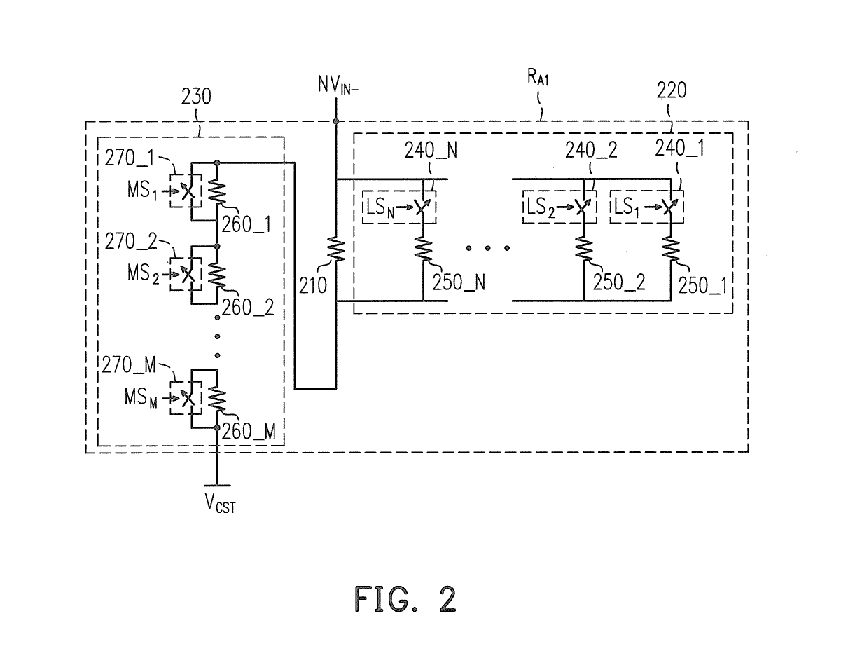

FIG. 2 illustrates the circuit structure of the resistor array R_{A1} according to the first embodiment of the present disclosure. Referring to FIG. 2, the resistor array R_{A1} includes a resistor 210, a LSB resistor string 220, and a MSB resistor string 230. The first end of the resistor 210 is the first end of the resistor array R_{A1}. The LSB resistor string 220 is connected with the resistor 210 in parallel. The first terminal of the MSB resistor string 230 is coupled to the second terminal of the LSB resistor string 220. In the present embodiment, the LSB resistor string 220 has N LSB switches 240_1-240_N and N LSB resistors 250_1-250_N. The first terminal of the i^{th} LSB switch 240_{—}i is coupled to the first terminal of the LSB resistor string 220, the i^{th} LSB resistor 250_{—}i is connected with the i^{th} LSB switch 240_{—}i in series, and the second end of the i^{th} LSB resistor 250_{—}i is coupled to the second terminal of the LSB resistor string 220, wherein i is a positive integer and 1≦i≦N. Thus, the i^{th} LSB switch 240_{—}i can turn on the first end of the i^{th} LSB resistor 250_{—}i and the first terminal of the LSB resistor string 220 according to the i^{th} LSB switch control signal LSᵢ.

The MSB resistor string 230 in FIG. 2 includes M MSB resistors 260_1-260_M and M MSB switches 270_1-270_M. The first end of the 1^{st} MSB resistor 260_1 is the first terminal of the MSB resistor string 230, and the M MSB resistors 260_1-260_M are connected with each other in series. The j^{th} MSB resistor 260_{—}j is connected with the j^{th} MSB switch 260_{—}j in parallel, and the second end of the M^{th} MSB resistor 260_M is coupled to the second terminal of the MSB resistor string 230, wherein j is a positive integer and 1≦j≦M. Thus, the j^{th} MSB switch 270_{—}j can turn on the first end and the second end of the j^{th} MSB resistor 260_{—}j according to a j^{th} MSB switch control signal MSⱼ. Assuming that the resistances of the resistor 210 and the LSB resistors 250_1-250_N are all R_{P} and the resistances of the MSB resistors 260_1-260_M are all R_{S}, then the resistor array control unit 130 in FIG. 1 can adjust the maximum resistance of the resistor array R_{A1} to be (R_{S}×M+R_{P}) and the minimum resistance of the resistor array R_{A1} to be R_{P}/(N+1) according to the resistor array control signal S_{RA1}.

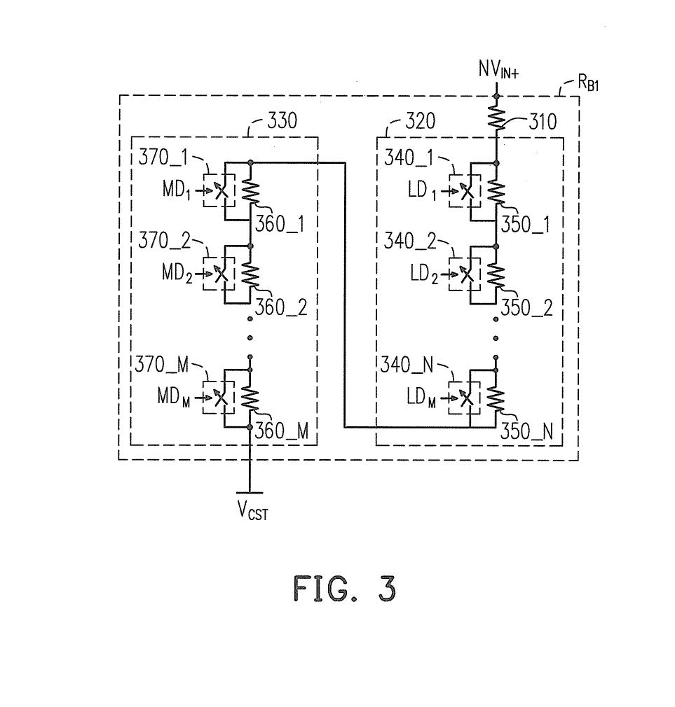

FIG. 3 illustrates the circuit structure of the resistor array R_{B1} according to the first embodiment of the present disclosure. Referring to FIG. 3, the resistor array R_{B1} includes a resistor 310, a LSB resistor string 320, and a MSB resistor string 330. Every two of the resistor 310, the LSB resistor string 320, and the MSB resistor string 330 are connected with each other in series. The first end of the resistor 310 is the first end of the resistor array R_{B1}, and the second terminal of the MSB resistor string 330 is the second end of the resistor array R_{B1}. The LSB resistor string 320 has N LSB switches 340_1-340_N and N LSB resistors 350_1-350_N, wherein every two of the N LSB resistors 350_1-350_N are connected with each other in series. The first end of the 1^{st} LSB resistor 350_1 is the first terminal of the LSB resistor string 320, and the second end of the N^{th} LSB resistor 350_N is the second terminal of the LSB resistor string 320. The i^{th} LSB resistor 350_{—}i is connected with the i^{th} LSB switch 340_1 in parallel. Thus, the i^{th} LSB switch 340_{—}i can turn on the first end and the second end of the i^{th} LSB resistor 350_{—}i according to the i^{th} LSB switch control signal LDᵢ. The circuit structure of the MSB resistor string 330 is, as that of the LSB resistor string 320, a serial variable resistor structure, wherein the N LSB resistors 350_1-350_N of the LSB resistor string 320 are replaced by M MSB resistors 360_1-360_M, and the N LSB switches 340_1-340_N of the LSB resistor string 320 are replaced by M MSB switches 370_1-370_M. The couplings between the MSB resistors 360_1-360_M and the MSB switches 370_1-370_M will not be described herein. Assuming that the resistance of the resistor 310 is R_{C}, the resistances of the LSB resistors 350_1-350_N are R_{N}, and the resistances of the MSB resistors 360_1-360_M are R_{M}, then the resistor array control unit 130 in FIG. 1 can adjust the maximum resistance of the resistor array R_{B1} to be (R_{C}+R_{M}×M+R_{N}×N) and the minimum resistance of the resistor array R_{B1} to be R_{C} according to the resistor array control signal S_{RB1}.

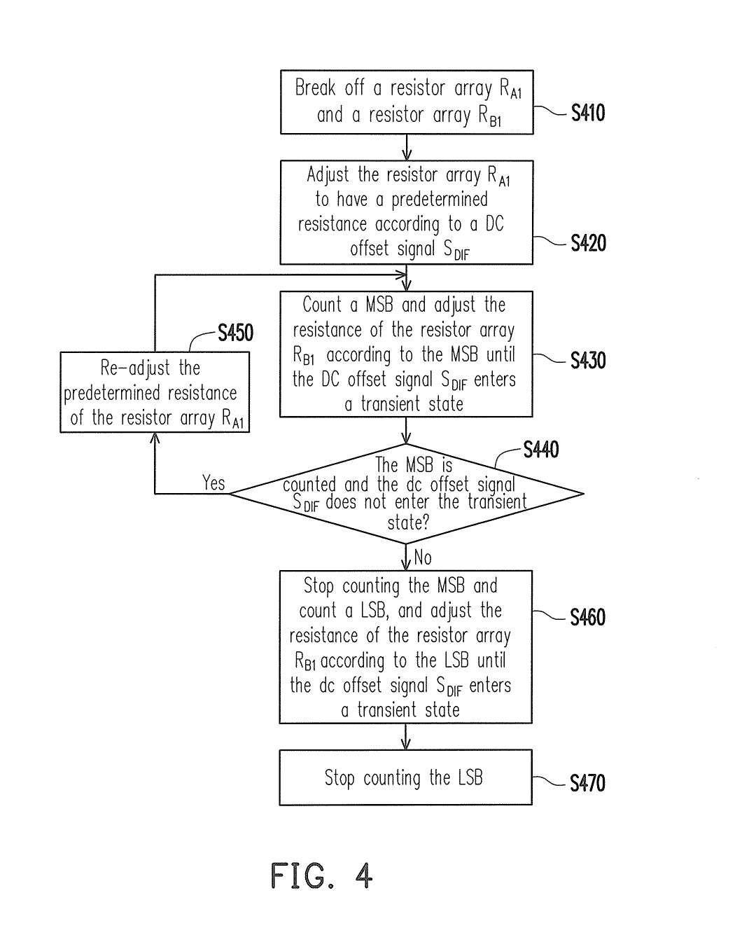

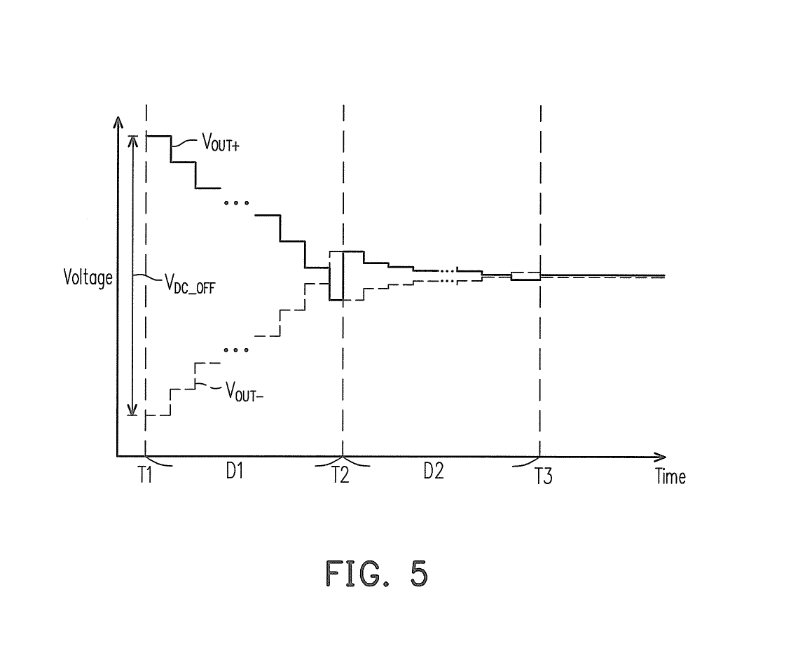

The DC offset calibration method provided in the present embodiment will be described herein. FIG. 4 is a flowchart of a DC offset calibration method according to the first embodiment of the present disclosure, and FIG. 5 is a diagram illustrating the DC offset calibration method according to the first embodiment of the present disclosure. Referring to FIG. 1, FIG. 4, and FIG. 5, in step S410, the resistor array control unit 130 breaks the resistor arrays R_{A1} and R_{B1} off the input terminals NV_{IN+} and NV_{IN-} by using the break-off signal S_{RR} and the switches 160 and 170. Then, in step S420, the resistor array control unit 130 adjusts the predetermined resistance of the resistor array R_{A1} according to the DC offset signal S_{DIF}, wherein the DC offset signal S_{DIF} is generated by the comparison unit 120 by detecting and determining the levels of the DC output voltage V_{OUT+} and DC output voltage V_{OUT-} of the output differential signal.

To be specific, the comparison unit 120 enables the DC offset signal S_{DIF} when the DC output voltage V_{OUT+} is higher than the DC output voltage V_{OUT-} (as shown in FIG. 5). Accordingly, the resistor array control unit 130 adjusts the resistor array R_{A1} to have the maximum resistance (R_{S}×M+R_{P}) and controls the resistance of the resistor array R_{B1} to be smaller than that of the resistor array R_{A1} in subsequent adjustment process so as to calibrate, or even eliminate, the DC offset voltage V_{DC}_{_{—}}_{OFF} in the output differential signal (the DC offset voltage V_{DC}_{_{—}}_{OFF} in FIG. 5 is the level difference between the DC output voltage V_{OUT+} and the DC output voltage V_{OUT-}). On the other hand, the comparison unit 120 disables the DC offset signal S_{DIF} when the DC output voltage V_{OUT+} is lower than the DC output voltage V_{OUT-}. Accordingly, the resistor array control unit 130 adjusts the resistor array R_{A1} to have the minimum resistance R_{P}/(N+1) and controls the resistance of the resistor array R_{B1} to be greater than that of the resistor array R_{A1} in subsequent adjustment process.

In other words, the DC offset signal S_{DIF} may also be considered as the polarity sign of the DC offset voltage V_{DC}_{_{—}}_{OFF}. When the DC output voltage V_{OUT+} is higher than the DC output voltage V_{OUT-}, the DC offset voltage V_{DC}_{_{—}}_{OFF} is greater than 0, the polarity sign thereof is positive, and the DC offset signal S_{DIF} is enabled. When the DC output voltage V_{OUT+} is lower than the DC output voltage V_{OUT-}, the DC offset voltage V_{DC}_{_{—}}_{OFF} is smaller than 0, the polarity sign thereof is negative, and the DC offset signal S_{DIF} is disabled. It should be noted that when the DC offset signal S_{DIF} enters a transient state, the DC output voltage V_{OUT+} that is originally lower than the DC output voltage V_{OUT-} becomes higher than the DC output voltage V_{OUT-}, or the DC output voltage V_{OUT+} that is originally higher than the DC output voltage V_{OUT-} becomes lower than the DC output voltage V_{OUT-}).

After the resistor array R_{A1} is adjusted to have the predetermined resistance, in step S430, the resistor array control unit 130 starts to count M MSB and changes the MSB switch control signals MD₁-MD_{M} according to the MSB, so as to adjust the resistance of the resistor array R_{B1} until the DC offset signal S_{DIF} enters a transient state. For example, as shown in FIG. 5, the DC output voltage V_{OUT+} is higher than the DC output voltage V_{OUT-} at the time T1. During the period D1 (i.e., the time T1-T2) in FIG. 5, the voltage levels of the DC output voltage V_{OUT+} and the DC output voltage V_{OUT-} get closer to each other every time when the resistor array control unit 130 counts one MSB, so that the affection of the DC offset voltage V_{DC}_{_{—}}_{OFF} over the output differential signal is reduced. In step S430, if the MSB has been counted from 1 to the M^{th} power of 2 (i.e., the counting operation is completed) but the DC offset signal S_{DIF} does not enter the transient state (i.e., the DC output voltage V_{OUT+} is always higher than the DC output voltage V_{OUT-}), the procedure proceeds from step S440 to step S450 so as to adjust the predetermined resistance of the resistor array R_{A1} again.

Contrarily, at the time T2 in FIG. 5, when the DC output voltage V_{OUT+} is lower than the DC output voltage V_{OUT-} (i.e., the DC offset signal S_{DIF} enters the transient state), the procedure proceeds from step S440 to step S460, and the resistor array control unit 130 resumes to the previous MSB value and stops counting the MSB. Next, the resistor array control unit 130 starts to count N LSB to change the LSB switch control signals LD₁-LD_{N}, and during the period D2 (i.e., the time T2-T3), the resistor array control unit 130 continuously controls the voltage levels of the DC output voltage V_{OUT+} and the DC output voltage V_{OUT-} to get closer to each other until the DC output voltage V_{OUT+} is lower than the DC output voltage V_{OUT-} again (i.e., at the time T3 when the DC offset signal S_{DIF} enters the transient state). In step 470, the resistor array control unit 130 stops counting the LSB. The resistor array control unit 130 adjusts the resistor array R_{B1} according to the calibrated MSB and LSB so as to eliminate the DC offset voltage V_{DC}_{_{—}}_{OFF}. Additionally, as shown in FIG. 5, the resistance variation of each MSB during the period D1 is greater than that of each LSB during the period D2 so that resistance of the resistor array R_{B1} can be quickly adjusted to an approximate value. Besides, the resistance variation of all counted LSB is greater than that of one MSB, so that the resistance of the resistor array R_{B1} can be precisely adjusted to a constant value to eliminate the DC offset voltage V_{DC}_{_{—}}_{OFF}.

In the present embodiment, the resistances of the resistor arrays are gradually adjusted by counting the MSB and the LSB, so that the DC output voltage V_{OUT+} and the DC output voltage V_{OUT-} are slowly equalized and the DC offset voltage V_{DC}_{_{—}}_{OFF} is gradually eliminated. In other embodiments of the present disclosure, there may be more different types of bit codes, and these bit codes may be gradually and sequentially adjusted to eliminate the DC offset voltage V_{DC}_{_{—}}_{OFF} more precisely. However, these embodiments will not be described herein.

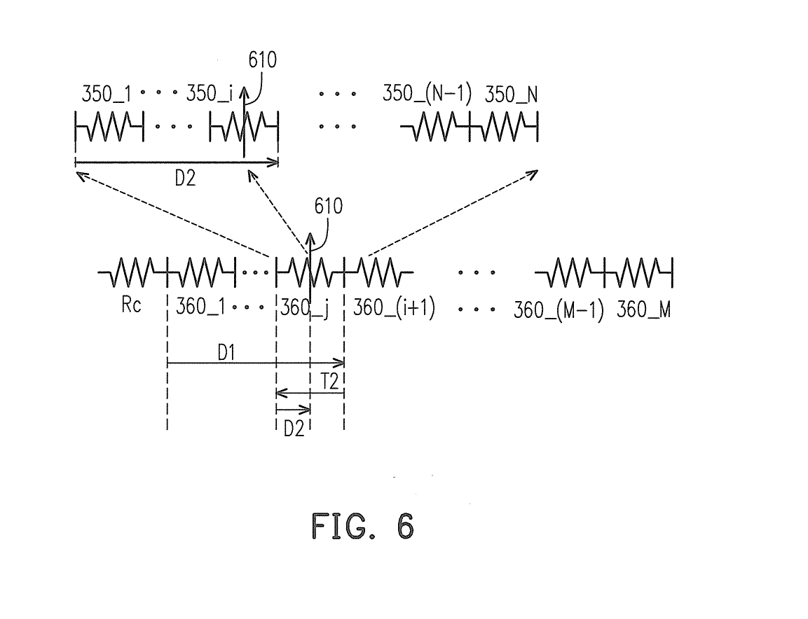

The relationship between the resistances of the resistor R_{C}, the MSB resistors 360_1-360_M, and the LSB resistors 350_1-350_N of the resistor array R_{B1} in FIG. 3 will be described herein in order to allow those skilled in the art to better understand the present embodiment. FIG. 6 is a diagram of the resistor array R_{B1} in FIG. 3. As shown in FIG. 6, the arrow 610 indicates the resistance of the resistor array R_{B1} when the DC offset signal S_{DIF} enters a transient state (i.e., the resistance of the resistor array R_{B1} after the DC offset voltage is calibrated). First, the resistor array control unit 130 adjusts the resistance of the resistor array R_{B1} from R_{C} to (R_{C}+R_{M}×j) during the period D1 (i.e., when the MSB is counted from 1 to j). Since the resistance of the resistor array R_{B1} has been adjusted to the value indicated by the arrow 610, the DC offset signal S_{DIF} enters the transient state. The resistor array control unit 130 adjusts the resistance of the resistor array R_{B1} back to [R_{C}+R_{M}×(j+1)] at time T2 and continues to count the LSB during the period D2. When the resistor array control unit 130 counts the LSB from 1 to i, the resistance of the resistor array R_{B1} has been adjusted to the value indicated by the arrow 610. Thus, the DC offset signal S_{DIF} enters the transient state, and the resistor array control unit 130 stops counting the LSB. Thereby, the DC offset voltage can be calibrated the most precisely.

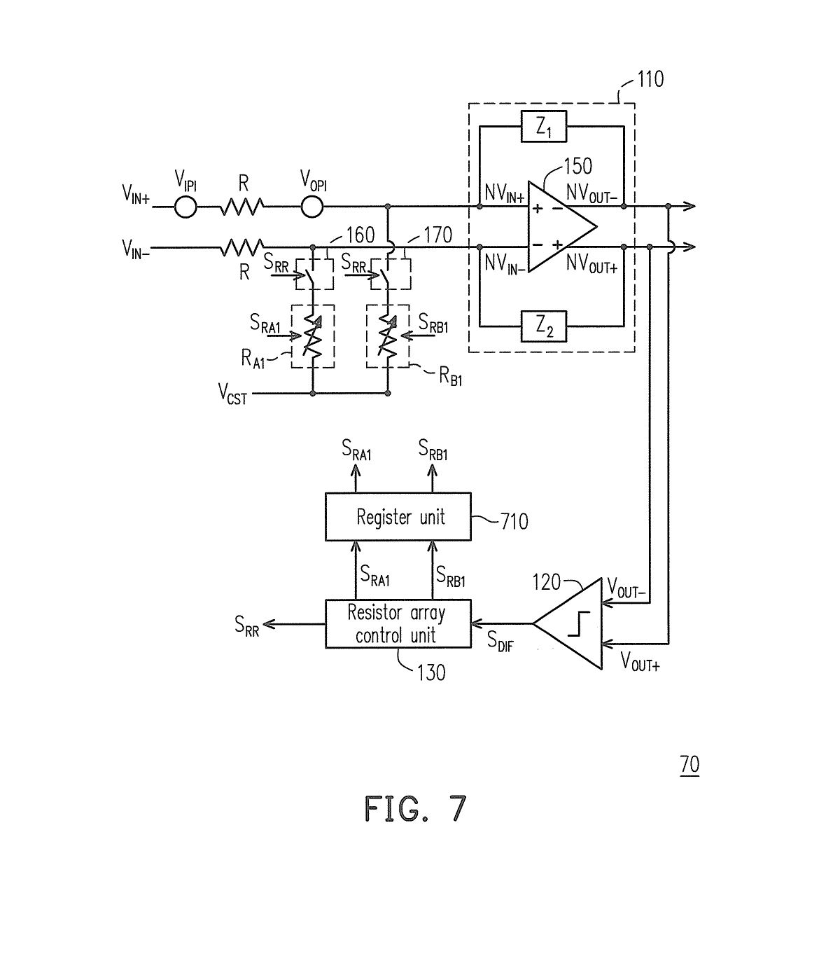

FIG. 7 is a block diagram of a DC offset calibration apparatus 70 according to a second embodiment of the present disclosure. Referring to FIG. 7, the difference between the present embodiment and the first embodiment is that the DC offset calibration apparatus 70 further includes a register unit 710. The register unit 710 stores the resistor array control signal S_{RA1} and the resistor array control signal S_{RB1} that have been calibrated by the resistor array control unit 130, so that the DC offset calibration apparatus 70 can directly use the previously calibrated signals for adjusting the resistances of the resistor array R_{A1} and the resistor array R_{B1} when next time the DC offset calibration apparatus 70 is powered on. Thus, the DC offset calibration apparatus 70 needs not to carry out the calibration every time when it is powered on and the time it spends on stabilizing signals is shortened.

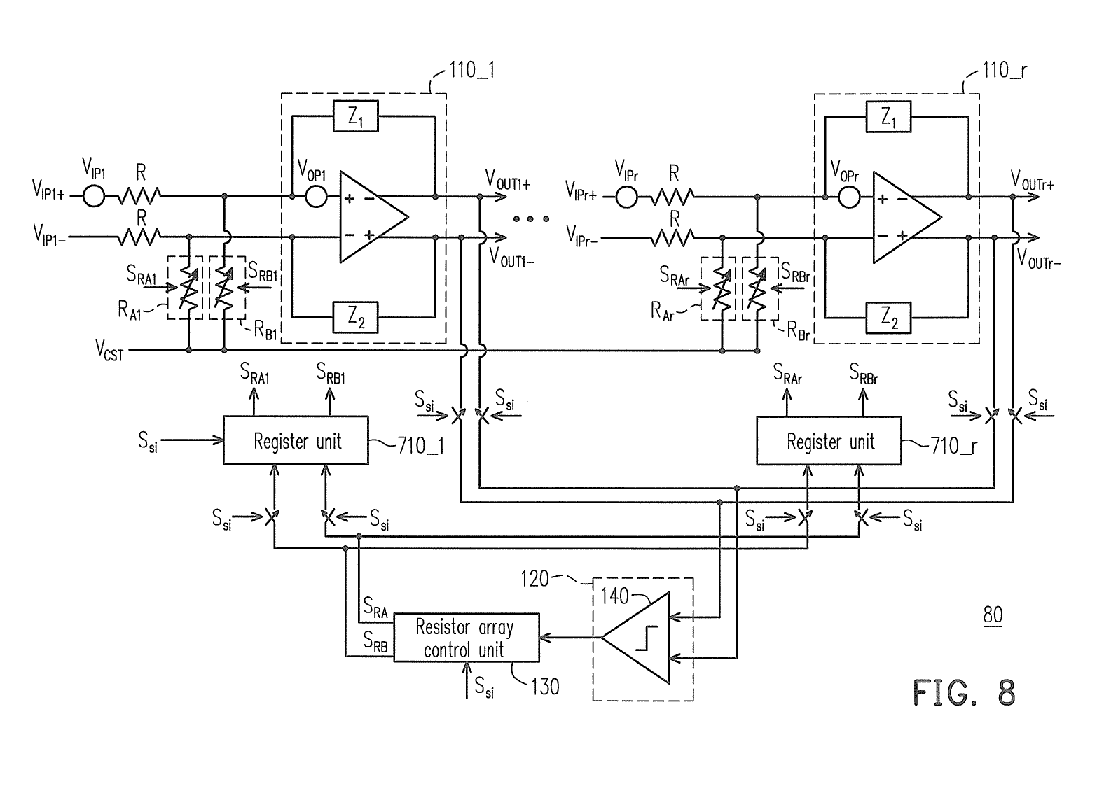

In a DC offset calibration system 80 provided by a third embodiment of the present disclosure, the comparison unit 120 and the resistor array control unit 130 are shared by a plurality of signal processing units 110_1-110_{—}r so that the circuit area of the DC offset calibration system 80 can be reduced, wherein r is a positive integer. FIG. 8 is a block diagram of the DC offset calibration system 80 according to the third embodiment of the present disclosure. As shown in FIG. 8, in the present embodiment, each of the signal processing units 110_1-110_{—}r, the resistor arrays R_{A1}-R_{Ar}, the resistor arrays R_{B1}-R_{Br}, and the register units 710_1-710_{—}r is the same as the corresponding one of the signal processing unit 110, the resistor arrays R_{A1} and R_{B1}, and the register unit 710 in foregoing embodiments. The comparison unit 120 and the resistor array control unit 130 calibrate the DC offset voltage regarding one of the signal processing units 110_1-110_{—}r according to a switch signal S_{Si} and store the calibration result into the corresponding one of the register units 710_1-710_{—}r. The calibration process has been described in foregoing embodiments therefore will not be described herein. As described above, in the present embodiment, the DC offset signals in multiple signal processing units 110_1-110_{—}r can be calibrated by using a single resistor array control unit 130 and a single comparison unit 120, so that the circuit area can be reduced.

In summary, in an embodiment of the present disclosure, a resistor array control unit adjusts the resistances of resistor arrays located at the input terminal according to a DC offset signal and the sequence of bit codes until the DC offset signal enters a transient state, so that the resistor array control unit can compensate for the DC offset voltage in an output differential signal by using the currents generated by the resistor arrays and a compensation voltage. Accordingly, both the surface area and the power consumption of the circuit can be reduced. In addition, a DC offset calibration apparatus provided by an embodiment of the present disclosure adopts an open-circuit design such that the DC offset calibration apparatus can instantly respond to the compensation state thereof and allow the resistor array control unit to adjust the resistances of the resistor arrays constantly. On the other hand, in a DC offset calibration system provided by an embodiment of the present disclosure, the same comparison unit and resistor array control unit may be shared by multiple signal processing units, and the calibrated control signals can be temporarily stored in register units, so that the DC offset calibration operation can be performed less number of times and both the surface area and the power consumption of the circuit can be reduced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A DC offset calibration apparatus, comprising:
a signal processing unit, comprising a first input terminal and a second input terminal, for receiving an input differential signal and generating an output differential signal;
a comparison unit, coupled to the signal processing unit, for detecting and determining levels of a first DC output voltage and a second DC output voltage of the output differential signal so as to generate a DC offset signal;
a first resistor array and a second resistor array, wherein a first end of the first resistor array and a first end of the second resistor array are respectively coupled to the first input terminal and the second input terminal, and a second end of the first resistor array and a second end of the second resistor array receive a compensation voltage; and
a resistor array control unit, for adjusting resistances of the first resistor array and the second resistor array according to the DC offset signal, so as to calibrate a DC offset voltage of the output differential signal.

2. The DC offset calibration apparatus according to claim 1, wherein the resistor array control unit adjusts the first resistor array to have a first predetermined resistance according to the DC offset signal and adjusts a resistance of the second resistor array according to a sequence of bit codes until the DC offset signal enters a transient state.

3. The DC offset calibration apparatus according to claim 2, wherein the resistor array control unit counts a most significant bit (MSB) to adjust the resistance of the second resistor array until the DC offset signal enters a transient state, and the resistor array control unit counts a least significant bit (LSB) adjust the resistance of the second resistor array until the DC offset signal enters a transient state, wherein a resistance variation for counting the MSB once is greater than a resistance variation for counting the LSB once, and a resistance variation for counting the LSB all the times is greater than the resistance variation for counting the MSB once.

4. The DC offset calibration apparatus according to claim 3, wherein when the MSB is counted and the DC offset signal does not enter the transient state, the resistor array control unit re-adjusts the resistance of the first resistor array.

5. The DC offset calibration apparatus according to claim 2, wherein when the first DC output voltage is higher than the second DC output voltage, the resistor array control unit adjusts the resistance of the second resistor array to be smaller than the first predetermined resistance, or when the first DC output voltage is lower than the second DC output voltage, the resistor array control unit adjusts the resistance of the second resistor array to be greater than the first predetermined resistance.

6. The DC offset calibration apparatus according to claim 3, wherein the resistor array control unit generates at least one first resistor array control signal and at least one second resistor array control signal according to the MSB and the LSB, so as to adjust the resistances of the first resistor array and the second resistor array.

7. The DC offset calibration apparatus according to claim 6, wherein the DC offset calibration apparatus further comprises:
a register unit, for storing the first resistor array control signal and the second resistor array control signal of the resistor array control unit.

8. The DC offset calibration apparatus according to claim 6, wherein the first resistor array control signal comprises at least one first LSB switch control signal and at least one first MSB switch control signal, and the second resistor array control signal comprises at least one second LSB switch control signal and at least one second MSB switch control signal.

9. The DC offset calibration apparatus according to claim 8, wherein the first resistor array comprises:
a first predetermined resistor, wherein a first end of the first predetermined resistor is the first end of the first resistor array;
a first LSB resistor string, connected with the first predetermined resistor in parallel; and
a first MSB resistor string, wherein a first terminal of the first MSB resistor string is coupled to the first predetermined resistor and a second terminal of the first LSB resistor string, and a second terminal of the first MSB resistor string is the second end of the first resistor array.

10. The DC offset calibration apparatus according to claim 9, wherein the first LSB resistor string comprises:
N first LSB switches and N first LSB resistors, wherein a first terminal of the i^{th} first LSB switch is coupled to a first terminal of the first LSB resistor string, a first end of the i^{th} first LSB resistor is coupled to a second terminal of the i^{th} first LSB switch, and a second end of the i^{th} first LSB resistor is coupled to the second terminal of the first LSB resistor string, wherein the i^{th} first LSB switch turns on the first end of the i^{th} first LSB resistor to the first terminal of the first LSB resistor string according to the i^{th} first LSB switch control signal, N and i are both positive integers, and 1≦i≦N.

11. The DC offset calibration apparatus according to claim 9, wherein the first MSB resistor string comprises:
M first MSB resistors and M first MSB switches, wherein a first end of the 1^{st} first MSB resistor is the first terminal of the first MSB resistor string, a first end of the j^{th} first MSB resistor is coupled to a first terminal of the j^{th} first MSB switch, a second end of the j^{th} first MSB resistor is coupled to a second terminal of the j^{th} first LSB switch and a first end of the (j+1)^{th} first MSB resistor, and a second end of the M^{th} first MSB resistor is coupled to the second end of the first resistor array, wherein the j^{th} first MSB switch turns on the first end and the second end of the j^{th} first MSB resistor according to the i^{th} first MSB switch control signal, M and j are both positive integers, and 1≦j≦M.

12. The DC offset calibration apparatus according to claim 8, wherein the second resistor array comprises:
a second predetermined resistor, wherein a first end of the second predetermined resistor is the first end of the second resistor array;
a second LSB resistor string, wherein a first terminal of the second LSB resistor string is coupled to a second end of the second predetermined resistor; and
a second MSB resistor string, wherein a first terminal of the second MSB resistor string is coupled to a second terminal of the second LSB resistor string, and a second terminal of the second MSB resistor string is the second end of the second resistor array.

13. The DC offset calibration apparatus according to claim 12, wherein the second LSB resistor string comprises:
N second LSB switches and N second LSB resistors, wherein a first end of the 1^{st} second LSB resistor is the first terminal of the second LSB resistor string, a first end of the i^{th} second LSB resistor is coupled to a first terminal of the i^{th} second LSB switch, a second end of the i^{th} second LSB resistor is coupled to a second terminal of the i^{th} second LSB switch and a first end of the (i+1)^{th} second LSB resistor, and a second end of the N^{th} second LSB resistor is coupled to the second terminal of the second LSB resistor string, wherein the i^{th} second LSB switch turns on the first end and the second end of the i^{th} second LSB resistor according to the i^{th} second LSB switch control signal, N and i are both positive integers, and 1≦i≦N.

14. The DC offset calibration apparatus according to claim 12, wherein the second MSB resistor string comprises:
M second MSB resistors and M second MSB switches, wherein a first end of the 1^{st} second MSB resistor is coupled to the first terminal of the second MSB resistor string, a first end of the j^{th} second MSB resistor is coupled to a first terminal of the j^{th} second MSB switch, and a second end of the j^{th} second MSB resistor is coupled to a second terminal of the j^{th} second LSB switch and a first end of the (j+1)^{th} second MSB resistor, wherein the j^{th} second MSB switch turns on the first end and the second end of the j^{th} second MSB resistor according to the j^{th} second MSB switch control signal, M and j are both positive integers, and 1≦j≦M.

15. The DC offset calibration apparatus according to claim 1, wherein the comparison unit comprises a hysteresis comparator.

16. A DC offset calibration method, suitable for a signal processing unit, a first resistor array, and a second resistor array, wherein the signal processing unit comprises a first input terminal and a second input terminal, and the signal processing unit generates an output differential signal, a first end of the first resistor array is coupled to the first input terminal, a first end of the second resistor array is coupled to the second input terminal, and second ends of the first resistor array and the second resistor array receive a compensation voltage, the DC offset calibration method comprising:
detecting and determining levels of a first DC output voltage and a second DC output voltage of the output differential signal, so as to generate a DC offset signal;
adjusting the first resistor array to have a first predetermined resistance according to the DC offset signal; and
adjusting a resistance of the second resistor array according to a sequence of bit codes until the DC offset signal enters a transient state, so as to calibrate a DC offset voltage of the output differential signal.

17. The DC offset calibration method according to claim 16, wherein the step of adjusting the resistance of the second resistor array according to the sequence of bit codes until the DC offset signal enters the transient state comprises:
counting a MSB to adjust the resistance of the second resistor array until the DC offset signal enters the transient state; and
counting a LSB to adjust the resistance of the second resistor array until the DC offset signal enters the transient state.

18. The DC offset calibration method according to claim 17 further comprising:
re-adjusting a resistance of the first resistor array when the MSB is counted and the DC offset signal does not enter the transient state.

19. The DC offset calibration method according to claim 16, wherein the step of the step of calibrating the DC offset voltage of the output differential signal comprises:
generating at least one first resistor array control signal and at least one second resistor array control signal according to the MSB and the LSB, so as to adjust resistances of the first resistor array and the second resistor array; and
storing the first resistor array control signal and the second resistor array control signal.

20. A DC offset calibration system, comprising:
N signal processing units, wherein each of the signal processing units comprises a first input terminal and a second input terminal, and each of the signal processing units receives an input differential signal and generates an output differential signal, wherein N is a positive integer;
N first resistor arrays and N second resistor arrays, wherein a first end of the i^{th} first resistor array is coupled to the first input terminal of the i^{th} signal processing unit, a first end of the i^{th} second resistor array is coupled to the second input terminal of the i^{th} signal processing unit, and second ends of the i^{th} first resistor array and the i^{th} second resistor array receive a compensation voltage, wherein i is a positive integer and 1≦i≦N;
a comparison unit, for detecting and determining levels of a first DC output voltage and a second DC output voltage in the output differential signal generated by the i^{th} signal processing unit, so as to generate a DC offset signal; and
a resistor array control unit, for adjusting resistances of the i^{th} first resistor array and the i^{th} second resistor array according to the DC offset signal, so as to calibrate a DC offset voltage of the output differential signal generated by the i^{th} signal processing unit.

21. The DC offset calibration system according to claim 20, wherein the resistor array control unit generates at least one first resistor array control signal and at least one second resistor array control signal according to the DC offset signal, so as to adjust the resistances of the i^{th} first resistor array and the i^{th} second resistor array.

22. The DC offset calibration system according to claim 20 further comprising:
N register units, wherein the i^{th} register unit stores the first resistor array control signal and the second resistor array control signal generated by the resistor array control unit.
